(19) United States
(12) Patent Application Publication
(10) Pub. No.: US 2025/0071942 A1
(43) Pub. Date: Feb. 27, 2025

(54) CONTROL DEVICE FOR HEAT DISSIPATION OF SERVER AND METHOD FOR CONTROLLING HEAT DISSIPATION OF SERVER

(71) Applicant: SUZHOU METABRAIN INTELLIGENT TECHNOLOGY CO., LTD., Suzhou, Jiangsu (CN)

(72) Inventor: Huanlai ZHU, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 18/724,112

(22) PCT Filed: Nov. 29, 2022
(86) PCT No.: PCT/CN2022/135156

§ 371 Date: Jun. 25, 2024

(30) Foreign Application Priority Data
Apr. 29, 2022 (CN) 202210462562.2

(51) Int. Cl. H05K 7/20; G06F 1/20

(52) U.S. Cl. CPC H05K 7/20318; G06F 1/20; H05K 7/203; H05K 7/20327; H05K 7/20818; H05K 7/20836

(57) ABSTRACT

Disclosed are a control device for a heat dissipation of a server and a method for controlling heat dissipation of a server. The control device for the heat dissipation of the server includes a box body, a cover plate, a heat dissipation working medium and a condensing module, wherein the server is arranged in the box body, and the cover plate is configured to close the box body; the heat dissipation working medium is arranged in the box body; and the condensing module is arranged on the box body, including a condensing coil and a flow guide driving member, wherein the condensing coil is configured to assist phase change of the heat dissipation working medium; and the flow guide driving member is arranged towards the condensing coil, and configured to control the heat dissipation working medium in a steam/gas state to flow towards the condensing coil.

### CROSS-REFERENCE TO RELATED DISCLOSURE

The present application is a National Stage Application of PCT International Application No.: PCT/CN2022/135156 filed on Nov. 29, 2022, which claims priority to Chinese Patent Application 202210462562.2, filed in the China National Intellectual Property Administration on Apr. 29, 2022, the disclosure of which is incorporated herein by reference in its entirety.

### TECHNICAL FIELD

The present disclosure relates to the technical field of servers, and in particular, to a control device for a heat dissipation of a server. The present disclosure further relates to a method for controlling heat dissipation of a server, which is applied to the control device for the heat dissipation of the server.

### BACKGROUND

Currently, in order to meet the ever-increasing computing power requirements of data centers, the power density of a single cabinet is becoming higher and higher. Under this context, heat dissipation technologies for liquid-cooled data centers with low PUE (abbreviation for Power Usage Effectiveness, which is an index for evaluating an energy efficiency of a data center) and high heat dissipation density emerge as required.

In a related art, a two-phase immersion liquid-cooled system uses a latent heat of vaporization phase change of a heat dissipation working medium to carry away heat quickly, which undoubtedly has a highest cooling efficiency and a highest heat dissipation density. In the two-phase immersion liquid-cooled system, a thermally-conductive engineering liquid (the heat dissipation working medium), such as a fluorinated liquid, needs to be arranged in an enclosed box body, and a server in the enclosed box body is immersed in the engineering liquid to achieve heat dissipation. However, when maintenance of the server is required, it is necessary to open a cover plate of the enclosed box body, which causes a leakage of the fluorinated liquid, leading to economic loss and safety risks caused by a large amount of leakage of the expensive fluorinated liquid.

### SUMMARY

An object of some embodiments of the present disclosure is to provide a control device for the heat dissipation of a server and a method for controlling heat dissipation of a server which is applied to the control device for the heat dissipation of the server, which are able to increase the heat dissipation efficiency, and solve the problems of loss due to leakage of a fluorinated liquid and potential safety risks when the cover of a box body is opened for maintenance of the server.

In order to achieve the object above, some embodiments of the present disclosure provide a control device for a heat dissipation of a server, configured for heat dissipation of the server and comprising:
a box body;
a cover plate, connected with the box body and configured to close the box body;
a heat dissipation working medium, arranged in the box body and configured to immerse the server; and
a condensing module, arranged in the box body and comprising:
a condensing coil, arranged in the box body and configured to assist phase change of the heat dissipation working medium, so as to achieve heat dissipation circulation; and
a flow guide driving member, arranged towards the condensing coil and configured to provide a driving force to control a gaseous heat dissipation working medium to flow towards the condensing coil, so as to prevent the gaseous heat dissipation working medium from impacting the cover plate when the cover plate is closed and prevent the gaseous heat dissipation working medium from leaking to an outside of the box body when the cover plate is opened;
wherein the condensing module further comprises a gas-liquid separator; the gas-liquid separator is arranged at an outlet of the flow guide driving member, and the gas-liquid separator is configured to separate an air and a droplet-shaped heat dissipation working medium.

In some embodiments, the flow guide driving member is arranged at a side close to an inlet of the condensing coil.

In some embodiments, an accommodating space is formed between the condensing coil and the box body, the flow guide driving member is arranged in the accommodating space, and the condensing coil covers the flow guide driving member in an arrangement direction of the server.

In some embodiments, the condensing coil is an S-shaped coil.

In some embodiments, the gas-liquid separator comprises a first baffle plate and a second baffle plate; the first baffle plate is connected with the flow guide driving member, and the second baffle plate is connected with the first baffle plate and is arranged at a preset included angle relative to the first baffle plate.

In some embodiments, the device further comprises a ventilation valve, wherein the ventilation valve is arranged on the cover plate, and an air separated by the gas-liquid separator is discharged out of the box body through the ventilation valve.

In some embodiments, the device further comprises:
a first pressure sensor, arranged between the cover plate and the box body and configured to detect a state of the cover plate;
a second pressure sensor, arranged on the cover plate and configured to measure a pressure in the box body; and
a control assembly, connected with the first pressure sensor, the second pressure sensor and the flow guide driving member, and configured to control an operation of the flow guide driving member according to pressure values measured by the first pressure sensor and the second pressure sensor.

In some embodiments, the device further comprises a pressure regulating valve, wherein the pressure regulating valve is arranged on the cover plate and is connected to the control assembly, and the pressure regulating valve is configured to regulate the pressure inside the box body.

Some embodiments of the present disclosure further provide a method for controlling heat dissipation of a server, applied to the control device for the heat dissipation of a server of any one above and comprising:
it is determined whether the cover plate on the box body is closed;
if the cover plate is closed, it is determined whether a pressure in the box body is a first normal value;
if it is determined that the pressure in the box body is not the first normal value, the flow guide driving member is controlled to operate; after the heat dissipation working medium flows towards the condensing coil and is condensed by the condensing coil, the air and droplet-shaped heat dissipation working medium flow to the gas-liquid separator through the outlet of the flow guide driving member; the gas-liquid separator separates the air from the droplet-shaped heat dissipation working medium, and the air is discharged upwards out of the box body, so that the pressure in the box body is adjusted to the first normal value; and
if the cover plate is opened, it is determined whether the pressure in the box body is a second normal value; and
if the pressure in the box body is not the second normal value, the flow guide driving member is controlled to operate; after the heat dissipation working medium flows towards the condensing coil and is condensed by the condensing coil, the air and droplet-shaped heat dissipation working medium flow to the gas-liquid separator through the outlet of the flow guide driving member; the gas-liquid separator separates the air from the droplet-shaped heat dissipation working medium, and the air is discharged upwards out of the box body, so that the pressure in the box body is adjusted to the second normal value.

With respect to the background, a control device for a heat dissipation of a server provided in embodiments of the present disclosure is configured for heat dissipation of the server. The device specifically includes a box body, a cover plate, a heat dissipation working medium and a condensing module, wherein the server is arranged in the box body, the cover plate is connected with the box body, and the cover plate is configured to close the box body so as to improve an enclosed space for a heat dissipation circulation of the server; the heat dissipation working medium is arranged in the box body, and the server is immersed in the heat dissipation working medium, for heat dissipation of the server; and the condensing module is arranged in the box body. In some embodiments, the condensing module specifically includes a condensing coil, a flow guide driving member and a gas-liquid separator, wherein the condensing coil is arranged in the box body, the condensing coil is configured to assist phase change of the heat dissipation working medium, so as to achieve heat dissipation circulation. The phase change refers to a process in which the heat dissipation working medium vaporized into a gas state is condensed into a liquid after releasing heat on the condensing coil; the heat dissipation working medium condensed into the liquid state falls back into the box body under an action of gravity, thereby achieving the heat dissipation circulation; and the flow guide driving member is arranged towards the condensing coil, and the flow guide driving member is configured to provide a driving force to control the heat dissipation working medium in a steam/gas state to flow towards the condensing coil; and the gas-liquid separator is arranged at an outlet of the flow guide driving member, and the gas-liquid separator is configured to separate an air and a droplet-shaped heat dissipation working medium. In this way, the following beneficial effects are able to be brought about:
firstly, a gaseous heat dissipation working medium is able to be sufficiently condensed on the condensing coil, thereby greatly increasing the condensation efficiency;
secondly, the gaseous heat dissipation working medium is able to be prevented from impacting the cover plate when the cover plate is closed; if the heat dissipation working medium impacts the cover plate and then rebounds back and flows to the condensing module, the pressure loss will be increased, which is equivalent to increasing the temperature drop of the steam and indirectly decreasing the condensation efficiency, and therefore the gaseous heat dissipation working medium is able to be prevented from impacting the cover plate, thereby further increasing the condensation efficiency;
thirdly, the gaseous heat dissipation working medium is able to be prevented from leaking to an outside of the box body when the cover plate is opened; that is to say, a flowing direction of the heat dissipation working medium is changed by the flow guide driving member, so as to prevent the heat dissipation working medium from leaking to the outside of the box body; and
fourthly, in the embodiments of the present disclosure, on a basis of providing the condensing coil and the flow guide driving member, flow guide driving of fluorinated liquid steam is achieved by the flow guide driving member, thus, a guided fluorinated liquid steam is completely condensed on the condensing coil, an outlet position of the flow guide driving member mainly comprises small-particle droplets of the fluorinated liquid and a small amount of air, and the outlet of the flow guide driving member is provided with the gas-liquid separator. Due to different densities of gas and liquid, when a mixed flow encounters an obstacle, the gas will be diverted and flow away; the liquid has a continuous forward speed due to inertia, the forward liquid is attached to the gas-liquid separator, and is gathered together downwards due to an action of gravity, and finally drops back to an inside of the box body; however, the air will be diverted and flow upward due to the small density thereof, and is discharged to the outside of the box body through a top of the box body, so that the pressure in the box body is able to be always maintained at a normal value, which facilitates to ensure the stability of the operation of the system.

In addition, the method for controlling heat dissipation of a server provided by the embodiments of the present disclosure is applied to the control device for the heat dissipation of the server, and includes: it is determined whether the cover plate on the box body is closed; if the cover plate is closed, it is determined whether the pressure in the box body is the first normal value; if it is determined that the pressure in the box body is not the first normal value, the flow guide driving member is controlled to operate; after the heat dissipation working medium flows towards a condensing coil and is condensed by the condensing coil, the air and droplet-shaped heat dissipation working medium flow to the gas-liquid separator through the outlet of the flow guide driving member; the gas-liquid separator separates the air from the droplet-shaped heat dissipation working medium, and the air is discharged upwards out of the box body, so that the pressure in the box body is adjusted to the first normal value; and if the cover plate is opened, it is determined whether the pressure in the box body is the second normal value; and if the pressure in the box body is not the second normal value, the flow guide driving member is controlled to operate; after the heat dissipation working medium flows towards the condensing coil and is condensed by the condensing coil, the air and droplet-shaped heat dissipation working medium flow to the gas-liquid separator through the outlet of the flow guide driving member; the gas-liquid separator separates the air from the droplet-shaped heat dissipation working medium, and the air is discharged upwards out of the box body, so that the pressure in the box body is adjusted to the second normal value. The arrangement manner above is able to maintain the pressure in the box body to be the normal value, thereby increasing the heat dissipation efficiency of the server.

Compared with conventional heat dissipation of the server, the device and method for controlling heat dissipation of a server provided in embodiments of the present disclosure are able to increase the condensation efficiency, thereby increasing the heat dissipation efficiency; in addition, the leakage of the fluorinated liquid when the cover of the box body is opened for maintenance of the server is able to be solved, so that not only the loss of the fluorinated liquid is able to be reduced, but also the problem of potential safety risks caused by the leakage of the fluorinated liquid is able to be solved, thereby improving the safety.

### BRIEF DESCRIPTION OF THE DRAWINGS

In order to describe the technical solutions in the embodiments of the present disclosure or in the related art more clearly, hereinafter, accompanying drawings requiring to be used in the embodiments or the related art will be introduced briefly. Apparently, the accompanying drawings in the following description merely relate to embodiments of the present disclosure, and for a person of ordinary skill in the art, other accompanying drawings can also be obtained according to the provided accompanying drawings without involving any inventive effort.

FIG. 1 is a schematic diagram of an overall structure of a control device for a heat dissipation of a server with a cover not opened according to embodiments of the present disclosure;

FIG. 2 is a side view of the control device for a heat dissipation of a server as shown in FIG. 1;

FIG. 3 is a schematic diagram of heat dissipation of the control device for a heat dissipation of a server as shown in FIG. 2;

FIG. 4 is a schematic structural diagram of a condensing module in FIG. 2;

FIG. 5 is a top view of the control device for a heat dissipation of a server as shown in FIG. 1;

FIG. 6 is a front view of the control device for a heat dissipation of a server as shown in FIG. 1;

FIG. 7 is a schematic diagram of an overall structure of a control device for a heat dissipation of a server after a cover is opened according to embodiments of the present disclosure; and

FIG. 8 is a flowchart of a method for controlling heat dissipation of a server according to embodiments of the present disclosure.

In the drawings:
1—control device for the heat dissipation of a server;
10—Box body, 11—Cover plate, 12—Ventilation valve, 13—Solenoid valve, 14—Mechanical pressure relief valve, 15—First pressure sensor, 16—Second pressure sensor, 17—Liquid level meter and temperature sensor;
101—Heat dissipation working medium;
102—Condensing module, 1021—Condensing coil, 1022—Flow guide driving member, 1023—Gas-liquid separator, 10231—First baffle plate, 10232—Second baffle plate;
103—Server.

### DETAILED DESCRIPTION OF THE EMBODIMENTS

Hereinafter, the technical solutions in embodiments of the present disclosure will be described clearly and thoroughly with reference to the accompanying drawings of the embodiments of the present disclosure. Obviously, the embodiments as described are only some of the embodiments of the present disclosure, and are not all of the embodiments of the present disclosure. All other embodiments obtained by a person of ordinary skill in the art on the basis of the embodiments of the present disclosure without any inventive effort shall all fall within the scope of protection of the present disclosure.

The core of some embodiments of the present disclosure is to provide a control device for a heat dissipation of a server and a method for controlling heat dissipation of a server which is applied to the control device for the heat dissipation of the server, which is able to increase the heat dissipation efficiency, and solve the problems of loss due to leakage of a fluorinated liquid and potential safety risks when a cover of a box body is opened for maintenance of the server.

To make a person skilled in the art better understand the solutions of some embodiments of the present disclosure, hereinafter, some embodiments of the present disclosure are further described in detail with reference to the accompanying drawings and the specific embodiments.

It should be noted that, the orientation terms such as “upper end, lower end, left side and right side” described below are all defined on the basis of the drawings accompanying the description.

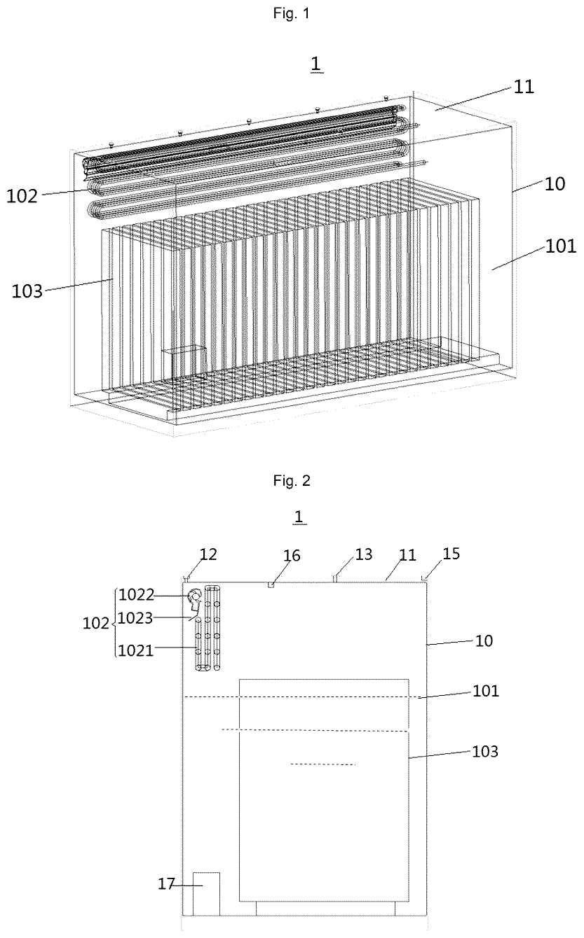

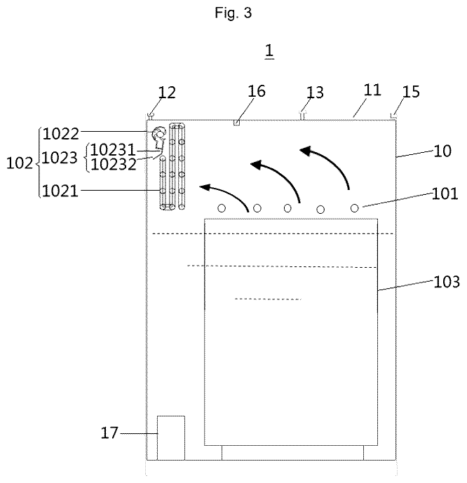

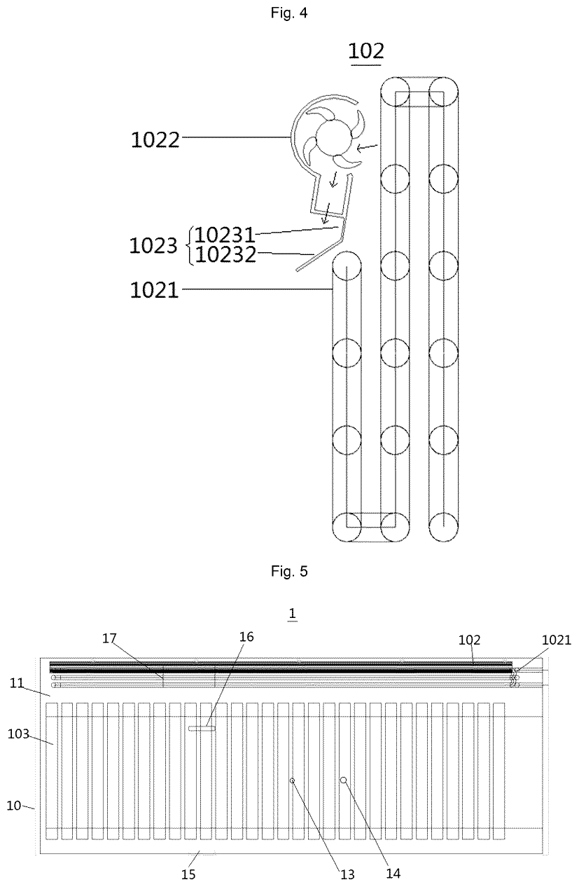

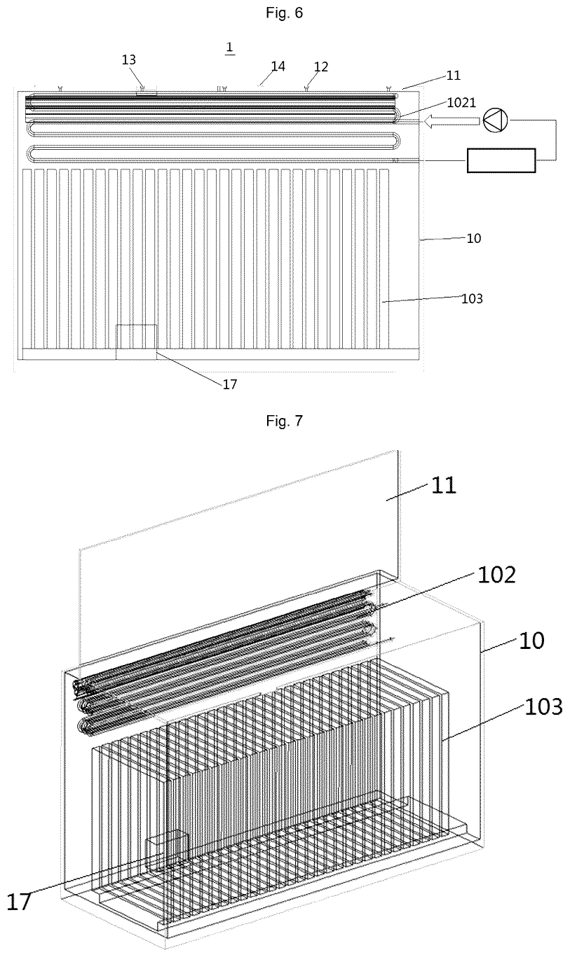

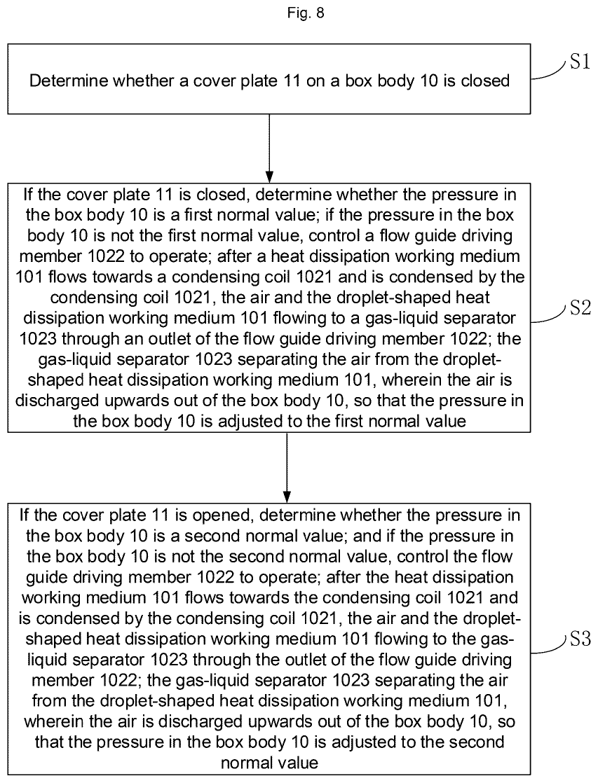

Please refer to FIGS. 1-8, FIG. 1 is a schematic diagram of an overall structure of a control device for a heat dissipation of a server with a cover not opened according to embodiments of the present disclosure; FIG. 2 is a side view of the control device for a heat dissipation of a server as shown in FIG. 1; FIG. 3 is a schematic diagram of heat dissipation of the control device for a heat dissipation of a server as shown in FIG. 2; FIG. 4 is a schematic structural diagram of a condensation module in FIG. 2; FIG. 5 is a top view of the control device for a heat dissipation of a server as shown in FIG. 1; FIG. 6 is a front view of the control device for a heat dissipation of a server as shown in FIG. 1; FIG. 7 is a schematic diagram of an overall structure of a control device for a heat dissipation of a server after a cover is opened according to embodiments of the present disclosure; and FIG. 8 is a flowchart of a method for controlling heat dissipation of a server according to embodiments of the present disclosure.

The control device 1 for the heat dissipation of the server provided in embodiments of the present disclosure is configured for heat dissipation of the server 103. The device specifically includes a box body 10, a cover plate 11, a heat dissipation working medium 101 and a condensing module 102, wherein the server 103 is arranged in the box body 10, the cover plate 11 is connected with the box body 10, and the cover plate 11 is configured to close the box body 10 so as to improve an enclosed space for heat dissipation circulation of the server 103; the heat dissipation working medium 101 is arranged in the box body 10, and the server 103 is immersed in the heat dissipation working medium 101, and configured for heat dissipation of the server 103; and the condensing module 102 is arranged in the box body 10, and the condensing module 102 is configured to provide a condensing working condition, so that the heat dissipation working medium 101 in a gas state is condensed into a liquid after releasing heat.

In some embodiments, the heat dissipation working medium 101 may use a fluorinated liquid.

In some embodiments, the condensing module 102 specifically includes a condensing coil 1021 and a flow guide driving member 1022. The condensing coil 1021 is arranged in the box body 10, and the condensing coil 1021 is configured to assist phase change of the heat dissipation working medium 101, so as to achieve heat dissipation circulation. It should be noted that the phase change refers to a process in which the heat dissipation working medium 101 vaporized into a gas state is condensed into a liquid after releasing heat on the condensing coil 1021; the heat dissipation working medium 101 condensed into the liquid state falls back into the box body 10 under an action of gravity, thereby achieving the heat dissipation circulation; and the flow guide driving member 1022 is arranged towards the condensing coil 1021, and the flow guide driving member 1022 is configured to provide a driving force to control the heat dissipation working medium 101 in a steam/gas state to flow towards the condensing coil 1021.

In this way, the arrangement manner above is able to bring about many beneficial effects, specifically including: firstly, a gaseous heat dissipation working medium 101 is able to be sufficiently condensed on the condensing coil 1021, thereby greatly increasing the condensation efficiency; secondly, the gaseous heat dissipation working medium 101 is able to be prevented from impacting the cover plate 11 when the cover plate 11 is closed; if the heat dissipation working medium 101 impacts the cover plate 11 and then rebounds back and flows to the condensing module 102, the pressure loss will be increased, which is equivalent to increasing the temperature drop of the steam and indirectly decreasing the condensation efficiency, and therefore the gaseous heat dissipation working medium 101 is able to be prevented from impacting the cover plate 11, thereby further increasing the condensation efficiency; and thirdly, the gaseous heat dissipation working medium 101 is able to be prevented from leaking to an outside of the box body 10 when the cover plate 11 is opened; that is to say, a flowing direction of the heat dissipation working medium 101 is changed by the flow guide driving member 1022, so as to prevent the heat dissipation working medium 101 from leaking to the outside of the box body 10.

Compared with conventional heat dissipation of the server 103, the control device 1 for the heat dissipation of the server provided in embodiments of the present disclosure is able to increase the condensation efficiency, thereby increasing the heat dissipation efficiency; in addition, the leakage of the fluorinated liquid when a cover of the box body 10 is opened for maintenance of the server 103 is able to be solved, so that not only the loss of the fluorinated liquid is able to be reduced, but also the problem of potential safety risks caused by the leakage of the fluorinated liquid is able to be solved, thereby improving the safety.

Certainly, according to actual needs, the flow guide driving member 1022 may specifically be configured as a cross-flow fan, an axial-flow fan, or the like. According to application scenarios of the present disclosure, the cross-flow fan is adopted in some embodiments of the present disclosure.

It can be understood that, in cases where no cross-flow fan is provided, the driving force for gas flowing of the fluorinated liquid is derived from a pressure difference between a positive pressure of an evaporation zone and a negative pressure of a condensation zone on an upper part of the server 103. In consideration of the leakage problem, an inside of the box body 10 is under a normal pressure control, and the pressure difference cannot be too large; in this way, most of the steam may impact the cover plate 11 during rising inside the box body 10, and then rebound back and flow to the condensing module 102, which increases the pressure loss, which is equivalent to increasing a temperature drop of the steam and indirectly decreasing the condensation efficiency. When the cover of the box body 10 needs to be opened for maintenance, this problem may cause a gas of the fluorinated liquid to flow directly to the outside of the box body 10, thereby causing a great loss of the expensive fluorinated liquid, which not only causes an economic loss but also causes a potential safety hazard.

By the control device 1 for the heat dissipation of a two-phase immersion liquid-cooled server proposed in some embodiments of the present disclosure, with the provision of the condensing module 102, during normal operation, a main driving force for flowing of steam is provided by a suction force of the cross-flow fan, thereby preventing the steam from directly impacting the cover plate 11 upwards and then bouncing back and reducing the local loss during steam impacting and bouncing back; moreover, in cases where the condensation zone maintains the same pressure, the pressure in the evaporation zone is able to be reduced, that is, a boiling point of the fluorinated liquid is reduced, and finally a temperature of chips inside the server 103 is reduced. If a same chip temperature is maintained, a thermal flux density of the chips is able to be increased, i.e. a high heat dissipation density is achieved.

That is to say, the arrangement manner above is able to fundamentally solve the problem of a large loss of fluorinated liquid steam when the cover of the box body 10 is opened for maintenance, and is able to also greatly increase the condensation efficiency of a condenser, achieve a high heat dissipation density, and reduce the costs of a heat dissipation apparatus per unit of power consumption.

In some embodiments, the flow guide driving member 1022 is arranged on a side close to an inlet of the condensing coil 1021.

When the cover of the box body 10 is opened for maintenance, the pressure inside the box body 10 is controlled by adjusting an operating speed of the cross-flow fan, so as to achieve a balance of air pressures inside and outside the box body 10, thereby preventing the steam from leaking to the outside of the box body 10. In this case, the cross-flow fan is arranged at or near an inlet side of the condensing coil 1021, and as the condensation capability at this position is the strongest, a fluorinated liquid steam suctioned by the cross-flow fan is completely condensed in the condensing module 102, thereby greatly increasing the condensation efficiency.

In some embodiments, an accommodating space is formed between the condensing coil 1021 and a side wall of the box body 10, the flow guide driving member 1022 is arranged in the accommodating space, and the condensing coil 1021 covers the flow guide driving member 1022 in an arrangement direction of the server 103.

That is to say, the flow guide driving member 1022 is arranged between the condensing coil 1021 and the side wall of the box body 10. The server 103 is generally arranged vertically in the box body 10, and therefore, the condensing coil 1021 covers the flow guide driving member 1022 in a vertical direction, which is able to ensure that the condensation zone in the box body 10 is large enough and the flow guide driving member 1022 is covered by the condensation zone.

In some embodiments, the condensing coil 1021 is specifically a coil having an S-shaped cross section.

In some embodiments, the inlet of the condensing coil 1021 is connected with a first end of a condensing pipeline located outside the box body 10, the condensing pipeline is provided with refrigeration assemblies such as a pump and a compressor, and an outlet of the condensing coil 1021 is connected with a second end of the condensing pipeline located outside the box body 10; in this way, refrigeration circulation is able to be realized. The structure of the S-shaped coil is able to increase the condensation area, thereby greatly increasing the condensation efficiency in the box body 10.

Taking the condensing module 102 arranged on a single side as an example, after a system is put in, the fluorinated liquid absorbs the heat generated by the server 103, is vaporized into a fluorinated liquid gas when the liquid reaches a saturation temperature, releases heat on the condensing coil 1021 and is condensed into a liquid, and falls back to the inside of the box body 10 under the action of gravity, thereby realizing heat dissipation circulation. Certainly, the condensing module 102 may also be arranged on two sides of the server 103 according to actual requirements.

In order to ensure the stability of the operation of the system, the condensing module 102 further includes a gas-liquid separator 1023; the gas-liquid separator 1023 is provided at an outlet of the flow guide driving member 1022, and the gas-liquid separator 1023 is configured to separate an air and a droplet-shaped heat dissipation working medium 101. In some embodiments, the gas-liquid separator 1023 includes a first baffle plate 10231 and a second baffle plate 10232; the first baffle plate 10231 is connected with an outlet housing of the flow guide driving member 1022, and the second baffle plate 10232 is connected with the first baffle plate 10231 and is arranged at a preset included angle relative to the first baffle plate 10231. A range of the preset included angle is able to be adjusted according to an outlet angle of the cross-flow fan, and the range of the preset included angle is generally greater than 90°.

In this way, on a basis of providing the condensing coil 1021 and the cross-flow fan, some embodiments of the present disclosure realize gas-liquid separation by the gas-liquid separator 1023. In some embodiments, the fluorinated liquid steam suctioned by the cross-flow fan is completely condensed on the condensing module 102, and under the driving of the cross-flow fan, small-particle droplets of the fluorinated liquid and a small amount of air enter the fan from a side of the fan close to the condensing coil 1021; then the small-particle droplets of the fluorinated liquid and the small amount of air flow out along an outlet at a bottom of the fan under a driving action of fan blades, and the outlet at the bottom of the fan is a through hole, that is, an outlet position of the cross-flow fan mainly includes the small-particle droplets of the fluorinated liquid and the small amount of air, and baffle plates with a certain angle are provided at an outlet of the cross-flow fan. By using the principle of baffle separation, i.e. due to different densities of gas and liquid, when a mixed flow encounters an obstacle, the gas will be diverted and flow away; the liquid has a continuous forward speed due to inertia, the forward liquid is attached to a blocking wall surface of the baffle plate, and is gathered together downwards due to the action of gravity, and finally drops back to the inside of the box body 10 at a bottom of the second baffle plate 10232; however, the air will be diverted and flow upward due to the small density thereof, and is discharged to the outside of the box body 10 through a top of the box body 10, so that a pressure in the box body 10 is able to be always maintained at a normal value, which facilitates to ensure the stability of the operation of the system.

In some embodiments, in order to facilitate air discharge, the control device for the heat dissipation of the server further includes a ventilation valve 12; the ventilation valve 12 is arranged at a bottom of the cover plate 11, and an air separated by the gas-liquid separator 1023 is discharged out of the box body 10 through the ventilation valve 12.

In some embodiments, the control device for the heat dissipation of the server further includes a pressure measurement assembly and a control assembly, wherein the pressure measurement assembly is arranged in the box body 10, and the pressure measurement assembly is configured to measure the pressure in the box body 10; the control assembly is connected with the pressure measurement assembly and the flow guide driving member 1022, and the control assembly is configured to control an operation of the flow guide driving member 1022 according to a pressure value measured by the pressure measurement assembly. The control assembly may be a PLC.

In some embodiments, the pressure measurement assembly may include a first pressure sensor 15 and a second pressure sensor 16; the first pressure sensor 15 is arranged between the cover plate 11 and the box body 10 or on the cover plate 11 and is configured to detect whether the cover plate 11 is in a closed state or an open state, and the second pressure sensor 16 is arranged at the bottom of the cover plate 11 and is configured to measure a pressure value in the box body 10; in addition, a liquid level meter and a temperature sensor 17 are further arranged inside the box body 10.

In some embodiments, the control device for the heat dissipation of the server further includes a pressure regulating valve; the pressure regulating valve is arranged on the cover plate 11 and is connected with the control assembly; the pressure regulating valve is configured to regulate the pressure inside the box body 10. For example, a solenoid valve 13 may be arranged at the bottom of the cover plate 11, and the solenoid valve 13 is controlled by the control assembly to achieve pressure regulation inside the box body 10. Of course, a mechanical safety valve (a mechanical pressure relief valve 14) may also be arranged on the bottom of the cover plate 11.

In addition, a method for controlling heat dissipation of a server provided by the embodiments of the present disclosure is applied to the control device 1 for the heat dissipation of the server, and includes:
S1: it is determined whether a cover plate 11 on a box body 10 is closed;
S2: if the cover plate 11 is closed, it is determined whether the pressure in the box body 10 is a first normal value; if the pressure in the box body 10 is not the first normal value, the flow guide driving member 1022 is controlled to operate; after the heat dissipation working medium 101 flows towards the condensing coil 1021 and is condensed by the condensing coil 1021, the air and droplet-shaped heat dissipation working medium 101 flow to the gas-liquid separator 1023 through the outlet of the flow guide driving member 1022; the gas-liquid separator 1023 separates the air from the droplet-shaped heat dissipation working medium 101, and the air is discharged upwards out of the box body 10, so that the pressure in the box body 10 is adjusted to the first normal value; and
S3: if the cover plate 11 is opened, it is determined whether the pressure in the box body 10 is a second normal value; and if the pressure in the box body 10 is not the second normal value, the flow guide driving member 1022 is controlled to operate; after the heat dissipation working medium 101 flows towards the condensing coil 1021 and is condensed by the condensing coil 1021, the air and droplet-shaped heat dissipation working medium 101 flow to the gas-liquid separator 1023 through the outlet of the flow guide driving member 1022; the gas-liquid separator 1023 separates the air from the droplet-shaped heat dissipation working medium 101, and the air is discharged upwards out of the box body 10, so that the pressure in the box body 10 is adjusted to the second normal value.

The arrangement manner above is able to maintain the pressure in the box body 10 to be the normal value, thereby increasing the heat dissipation efficiency of the server 103.

In some embodiments, the method for controlling heat dissipation of the server provided by the embodiments of the present disclosure specifically includes:
the system starts normally;
a data of the first pressure sensor 15 is acquired;
it is determined whether the cover plate 11 is closed according to the data detected by the first pressure sensor 15;
if the cover plate 11 is closed, a data of the second pressure sensor 16 is acquired, and it is determined whether the pressure in the box body 10 is the first normal value according to the data of the second pressure sensor 16; if the pressure in the box body 10 is not the first normal value, the flow guide driving member 1022 and/or the pressure regulating valve is controlled, so that the pressure in the box body 10 is adjusted to the first normal value; and
if the cover plate 11 is opened, a data of the second pressure sensor 16 is acquired, and it is determined whether the pressure in the box body 10 is the second normal value according to the data of the second pressure sensor 16; and if the pressure in the box body 10 is not the second normal value, the flow guide driving member 1022 is controlled, so that the pressure in the box body 10 is adjusted to the second normal value.

It should be noted that absolute values of the first normal value and the second normal value are different.

Certainly, before the step that the system starts normally, the method further includes: whether values of the liquid level meter and the temperature sensor in the box body 10 are normal, and if not, adjustment is performed until the values of the liquid level meter and the temperature sensor are both normal values.

It should be noted that in the present description, relational terms such as first and second, etc. are only used to distinguish one entity from several other entities, and do not necessarily require or imply any actual relationship or sequence between these entities.

Hereinabove, the device and method for controlling heat dissipation of a server provided in some embodiments of the present disclosure are described in detail. The principle and embodiments of the present disclosure are described herein by applying specific examples, and the illustration of the embodiments above is only used to help understand the solutions and core ideas of some embodiments of the present disclosure. It should be noted that, a person of ordinary skill in the art may further make several improvements and modifications to some embodiments of the present disclosure without departing from the principle of the present disclosure, and these improvements and modifications also belong to the scope of protection of the claims of the present disclosure.

1. A control device for a heat dissipation of a server, configured for heat dissipation of the server and comprising:
a box body;
a cover plate, connected with the box body and configured to close the box body;
a heat dissipation working medium, arranged in the box body and configured to immerse the server; and
a condensing module, arranged in the box body and comprising:
a condensing coil, arranged in the box body and configured to assist phase change of the heat dissipation working medium, so as to achieve heat dissipation circulation; and
a flow guide driving member, arranged towards the condensing coil and configured to provide a driving force to control a gaseous heat dissipation working medium to flow towards the condensing coil, so as to prevent the gaseous heat dissipation working medium from impacting the cover plate when the cover plate is closed and prevent the gaseous heat dissipation working medium from leaking to an outside of the box body when the cover plate is opened;
wherein the condensing module further comprises a gas-liquid separator; the gas-liquid separator is arranged at an outlet of the flow guide driving member, and the gas-liquid separator is configured to separate an air and a droplet-shaped heat dissipation working medium.

2. The control device (1) for the heat dissipation of the server as claimed in claim 1, wherein the flow guide driving member is arranged at a side close to an inlet of the condensing coil.

3. The control device for the heat dissipation of the server as claimed in claim 2, wherein an accommodating space is formed between the condensing coil and the box body, the flow guide driving member is arranged in the accommodating space, and the condensing coil covers the flow guide driving member in an arrangement direction of the server.

4. The control device for the heat dissipation of the server as claimed in claim 1, wherein the condensing coil is an S-shaped coil.

5. The control device for the heat dissipation of the server as claimed in claim 1, wherein the gas-liquid separator comprises a first baffle plate and a second baffle plate; the first baffle plate is connected with the flow guide driving member, and the second baffle plate is connected with the first baffle plate and is arranged at a preset included angle relative to the first baffle plate.

6. The control device for the heat dissipation of the server as claimed in claim 1, wherein the device further comprises a ventilation valve, wherein the ventilation valve is arranged on the cover plate, and an air separated by the gas-liquid separator is discharged out of the box body through the ventilation valve.

7. The control device for the heat dissipation of the server as claimed in claim 1, further comprising:
a first pressure sensor, arranged between the cover plate and the box body and configured to detect a state of the cover plate;
a second pressure sensor, arranged on the cover plate and configured to measure a pressure in the box body; and
a control assembly, connected with the first pressure sensor, the second pressure sensor and the flow guide driving member, and configured to control an operation of the flow guide driving member according to pressure values measured by the first pressure sensor and the second pressure sensor.

8. The control device for the heat dissipation of the server as claimed in claim 7, wherein the device further comprises a pressure regulating valve, wherein the pressure regulating valve is arranged on the cover plate and is connected with the control assembly, and the pressure regulating valve is configured to regulate the pressure inside the box body.

9. The control device for the heat dissipation of the server as claimed in claim 4, wherein an inlet of the condensing coil is connected with a first end of a condensing pipeline located outside the box body, the condensing pipeline is provided with a corresponding refrigeration assembly, and an outlet of the condensing coil is connected with a second end of the condensing pipeline located outside the box body.

10. The control device for the heat dissipation of the server as claimed in claim 5, wherein the condensing module is arranged at two sides of the server, and a range of the preset included angle is greater than 90°.

11. A method for controlling heat dissipation of a server, applied to the control device for the heat dissipation of the server as claimed in claim 1 and comprising:
determining whether the cover plate on the box body is closed;
if the cover plate is closed, determining whether a pressure in the box body is a first normal value;
if it is determined that the pressure in the box body is not the first normal value, controlling the flow guide driving member to operate; after the heat dissipation working medium flows towards the condensing coil and is condensed by the condensing coil, the air and the droplet-shaped heat dissipation working medium flowing to the gas-liquid separator through the outlet of the flow guide driving member; the gas-liquid separator separating the air from the droplet-shaped heat dissipation working medium, wherein the air is discharged upwards out of the box body, so that the pressure in the box body is adjusted to the first normal value; and
if the cover plate is opened, determining whether the pressure in the box body is a second normal value; and
if it is determined that the pressure in the box body is not the second normal value, controlling the flow guide driving member to operate; after the heat dissipation working medium flows towards the condensing coil and is condensed by the condensing coil, the air and the droplet-shaped heat dissipation working medium flowing to the gas-liquid separator through the outlet of the flow guide driving member; the gas-liquid separator separating the air from the droplet-shaped heat dissipation working medium, wherein the air is discharged upwards out of the box body, so that the pressure in the box body is adjusted to the second normal value.

12. The method as claimed in claim 11, wherein the flow guide driving member is arranged at a side close to an inlet of the condensing coil.

13. The method as claimed in claim 12, wherein an accommodating space is formed between the condensing coil and the box body, the flow guide driving member is arranged in the accommodating space, and the condensing coil covers the flow guide driving member in an arrangement direction of the server.

14. The method as claimed in claim 11, wherein the condensing coil is an S-shaped coil.

15. The method as claimed in claim 11, wherein the gas-liquid separator comprises a first baffle plate and a second baffle plate; the first baffle plate is connected with the flow guide driving member, and the second baffle plate is connected with the first baffle plate and is arranged at a preset included angle relative to the first baffle plate.

16. The method as claimed in claim 11, wherein the device further comprises a ventilation valve, wherein the ventilation valve is arranged on the cover plate, and an air separated by the gas-liquid separator is discharged out of the box body through the ventilation valve.

17. The method as claimed in claim 11, further comprising:
a first pressure sensor, arranged between the cover plate and the box body and configured to detect a state of the cover plate;
a second pressure sensor, arranged on the cover plate and configured to measure the pressure in the box body; and
a control assembly, connected with the first pressure sensor, the second pressure sensor and the flow guide driving member, and configured to control the operation of the flow guide driving member according to pressure values measured by the first pressure sensor and the second pressure sensor.

18. The method as claimed in claim 17, further comprising a pressure regulating valve, wherein the pressure regulating valve is arranged on the cover plate and is connected with the control assembly, and the pressure regulating valve is configured to regulate the pressure in the box body.

19. The method as claimed in claim 14, wherein an inlet of the condensing coil is connected with a first end of a condensing pipeline located outside the box body, the condensing pipeline is provided with a corresponding refrigeration assembly, and an outlet of the condensing coil is connected with a second end of the condensing pipeline located outside the box body.

20. The method as claimed in claim 15, wherein the condensing module is arranged at two sides of the server, and a range of the preset included angle is greater than 90°.
